(19) United States
(12) Patent Application Publication
(10) Pub. No.: US 2026/0246475 A1
(43) Pub. Date: Aug. 20, 2026

(54) DIRECT CONVERSION OF CAPACITIVE SENSORS WITH SAMPLED VOLTAGE NOISE CANCELATION

(71) Applicant: STMicroelectronics International N.V., Geneva (CH)

(72) Inventors: Roberto MODAFFARI, Domodossola (IT); Paolo PESENTI, Senago (IT)

(73) Assignee: STMicroelectronics International N.V., Geneva (CH)

(21) Appl. No.: 19/055,169

(22) Filed: Feb. 17, 2025

(51) Int. Cl. H03M 1/06; B81B 3/00

(52) U.S. Cl. CPC H03M 1/0607; H03M 1/0626; B81B 3/0021

(57) ABSTRACT

A capacitive sensing circuit includes a switched capacitor charge to voltage (C2V) converter circuit having an input coupled to a capacitive sensor and configured to receive a negative feedback signal. An offset and low-frequency noise cancelation circuit has an input coupled to an output of the switched capacitor C2V converter circuit. A sigma-delta analog-to-digital converter (ΣΔ-ADC) circuit includes a loop filter coupled to an output of the offset and low-frequency noise cancelation circuit, a quantizer coupled to an output of the loop filter and configured to generate a digital signal, and a digital-to-analog converter circuit configured to generate the negative feedback signal from the digital signal.

### TECHNICAL FIELD

The present invention generally relates to a circuit and method for cancelation of sampled voltage noise in the direct conversion of a capacitive sensor output.

### BACKGROUND

Capacitive Sensors, particularly those implemented using micro-electro-mechanical systems (MEMS) technologies, are widely used in a number of applications in the consumer market, the industrial market, and the automotive market. Conversion circuits are used for the readout of capacitive displacement in the sensor, where that displacement occurs in response to the variation of some external physical quantity (such as acceleration, angular rate, pressure, etc.).

The conversion circuitry used for readout can operate in Continuous-Time (CT) mode or Discrete-Time (DT) mode. DT mode is often preferred for use, and analog switched-capacitor (SC) circuitry is used for its implementation. The sampling operation performed by a SC circuit takes a sample on a capacitor and this operation implicates a thermal noise power added to the signal. This thermal noise power is known in the art as kT/C noise (where: k is Boltzmann's constant, T is absolute temperature, and C is capacitance). The noise is independent of the resistance of the sampling circuit.

To ensure accuracy of the sensing operation for capacitive displacement in the MEMS, it is necessary to reduce, or more preferably cancel, the kT/C noise.

### SUMMARY

In an embodiment, a capacitive sensing circuit comprises: a switched capacitor charge to voltage (C2V) converter circuit having an input coupled to a capacitive sensor and configured to receive a negative feedback signal; an auto-zeroing (AZ) circuit having an input coupled to an output of the switched capacitor C2V converter circuit; and a sigma-delta analog-to-digital converter (ΣΔ-ADC) circuit including a loop filter coupled to an output of the AZ circuit, a quantizer coupled to an output of the loop filter and configured to generate a digital signal, and a digital-to-analog converter circuit configured to generate the negative feedback signal from the digital signal.

### BRIEF DESCRIPTION OF THE DRAWINGS

For a better understanding of the embodiments, reference will now be made by way of example only to the accompanying figures in which:

FIG. 1 is a block diagram of a switched capacitor (SC) sensing chain;

FIG. 2 is a block diagram of a switched capacitor (SC) sigma-delta analog-to-digital converter (ΣΔ-ADC) circuit;

FIG. 3 is a block diagram of a SC sensing chain with auto-zeroing;

FIG. 4 is a schematic circuit diagram of the circuit shown in FIG. 3 using by example only a first-order ΣΔ-ADC circuit;

FIG. 5 shows a timing diagram for operation of the circuit shown in FIG. 4; and

FIG. 6 shows a circuit diagram for an alternative solution where the MEMS sensor is directly connected to the ADC circuit implemented, by example only, using a first-order ΣΔ-ADC circuit;

FIG. 7 is a block diagram of a SC sensing chain with auto-zeroing and improved feedback;

FIG. 8 is a schematic circuit diagram of the circuit shown in FIG. 7 using by example only a first-order ΣΔ-ADC circuit; and

FIG. 9 shows an example implementation of a multi-level (seven-level in the illustrated example) capacitive digital-to-analog converter (C-DAC) circuit used in the circuit of FIG. 8.

### DETAILED DESCRIPTION

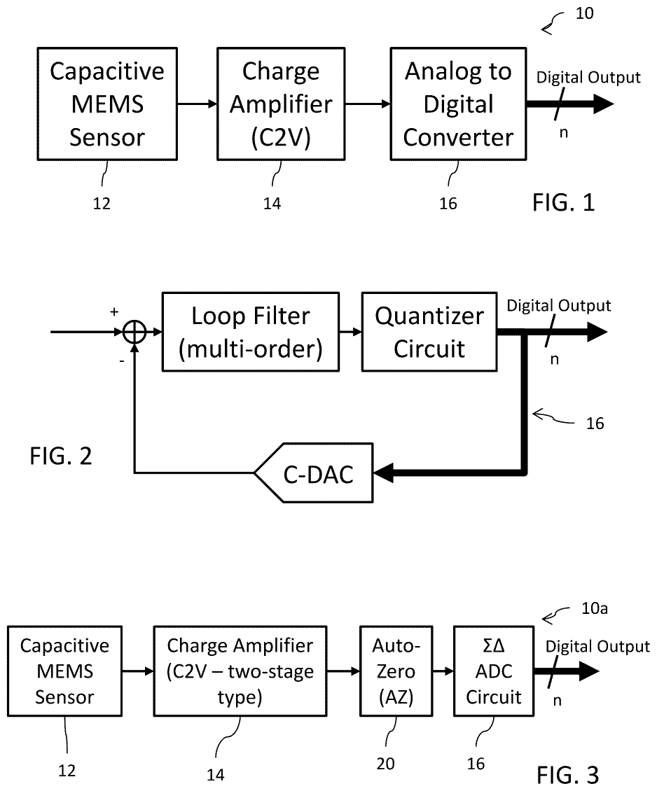

Reference is made to FIG. 1 which shows a block diagram of a switched capacitor (SC) sensing chain 10. A capacitive micro-electro-mechanical systems (MEMS) sensor 12 (for example, for the sensing of acceleration, angular rate, pressure, etc.) is connected to the input of a charge amplifier 14 that functions to translate a capacitive variation that takes place in the MEMS sensor 12 to a voltage signal. The functional operation performed by the charge amplifier 14 is often referred to in the art as a charge-to-voltage (C2V) conversion. The voltage signal output by the charge amplifier 14 is then converted to a digital signal in the digital domain by an analog-to-digital converter (ADC) circuit 16.

The ADC circuit 16 may, preferably, comprise a switched capacitor (SC) sigma-delta analog-to-digital converter (ΣΔ-ADC) circuit. A block diagram of such a switched capacitor ΣΔ-ADC circuit is shown in FIG. 2. The ΣΔ-ADC circuit is a modulator that comprises a Loop Filter of any suitable order, a quantizer circuit configured to convert the output of the Loop Filter to the digital domain and generate the digital output, and a capacitive digital-to-analog converter (DAC) circuit (C-DAC) that closes the feedback loop of the sigma-delta modulator. The working principle of this modulator circuit is that an error signal (given by the difference between the input signal generated by the charge amplifier and the feedback signal generated by the C-DAC, this difference being generated by the summation circuit) is injected and integrated in the loop filter and then the loop filter output is converted in the digital domain by the quantizer. Since the loop will act in negative feedback order to null this error signal, the digital output word will be a digital representation of the input signal.

Reference is now made to FIG. 3 which shows a block diagram of an improved SC sensing chain 10a which includes a circuit 20, placed between the output of the charge amplifier and the input of the ΣΔ-ADC circuit, that performs an offset and low-frequency noise cancelation function, referred to herein as an auto-zeroing (AZ) operation, of the voltage output by the charge amplifier circuit 14. This auto-zeroing operation is performed to cancel the charge amplifier offset and the kT/C noise that appears at the output of the charge amplifier and provide a dramatic improvement of the noise performance of the circuit.

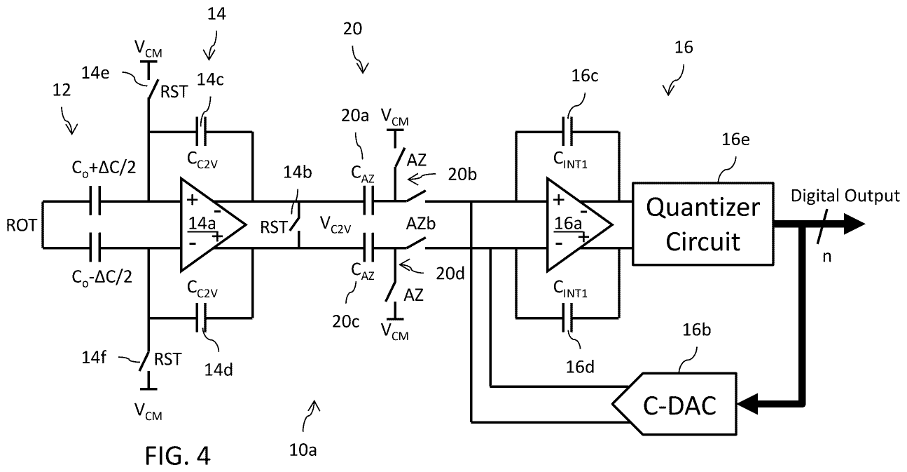

To clarify the concept, reference is made to FIG. 4 where the block scheme of the circuit 10a shown in FIG. 3 has been partially translated into a circuit schematic. The circuit of FIG. 4 shows a first-order implementation of the ΣΔ-ADC circuit where the loop filter comprises a switched capacitor integrator. It will be understood that this illustration is by (simplified) example only and that higher order loop filter circuits are compatible with, and likely to be used by, the modulator circuit. The MEMS sensor 12 generates a differential capacitance variation ΔC (which is the signal to be read) in response to variation of some external physical quantity (such as acceleration, angular rate, pressure, etc.), with the signal output from the MEMS sensor is coupled to the virtual ground of the charge amplifier 14.

The switched capacitor charge amplifier 14 includes a differential amplifier circuit 14a including a first (for example, non-inverting) input coupled to receive the differential signal component based on the capacitance

$${C}_{o} + \frac{Δ C}{2}$$

of the MEMS sensor 12 and a second (for example, inverting) input coupled to receive the differential signal component based on the capacitance

$${C}_{o} - \frac{Δ C}{2}$$

of the MEMS sensor 12. A square wave MEMS clock signal ROT is applied to a common node connection between the MEMS capacitors. A reset switch 14b is coupled between the first (for example, inverting) output and second (for example, non-inverting) output of the differential amplifier circuit 14a and actuated (i.e., closed) in response to assertion of a reset signal RST. A first capacitor 14c, having a capacitance value of C_{C2V}, is coupled in feedback between the first output and first input of the differential amplifier circuit 14a. A second capacitor 14d, having a capacitance value of C_{C2V}, is coupled in feedback between the second output and second input of the differential amplifier circuit 14a. A first common mode switch 14e is coupled between the first input of the differential amplifier circuit 14a and a common mode voltage V_{CM}.

A second common mode switch 14f is coupled between the second input of the differential amplifier circuit 14a and the common mode voltage V_{CM}. The switches 14e and 14f are actuated in response to assertion of the reset signal RST.

The differential output voltage V_{C2V} of the differential amplifier circuit 14a is coupled to the input of the auto-zeroing circuit 20. The auto-zeroing circuit 20 includes a first auto-zero capacitor 20a, having a capacitance CAZ, with a first terminal coupled to the first output of the differential amplifier circuit 14a and a second terminal coupled to a first auto-zero switch 20b. A second auto-zero capacitor 20c, having a capacitance CAZ, has a first terminal coupled to the second output of the differential amplifier circuit 14a and a second terminal coupled to a second auto-zero switch 20d. The switching operation of the first and second auto-zero switches 20b and 20d is controlled by logically inverted auto-zero control signals AZ, AZb. When the auto-zero control signal AZ is asserted (and thus the auto-zero control signal AZb is deasserted), the first and second auto-zero switches 20b and 20d couple the second terminals of the capacitors 20a, 20c to the common mode voltage V_{CM}. Conversely, when the auto-zero control signal AZb is asserted (and thus the auto-zero control signal AZ is deasserted), the first and second auto-zero switches 20b and 20d couple the second terminals of the capacitors 20a, 20c to the differential inputs, respectively, of the ΣΔ-ADC circuit 16.

The loop filter of the ΣΔ-ADC circuit 16 includes a differential amplifier circuit 16a having a first (for example, non-inverting) input coupled to capacitor 20a through the first auto-zero switch 20b (as well as receiving the feedback signal output from a first differential output of the C-DAC 16b) and a second (for example, inverting) input coupled to capacitor 20c through the second auto-zero switch 20d (as well as receiving the feedback signal output from a second differential output of the C-DAC 16b). A first integration capacitor 16c of the loop filter, having a capacitance value of CINTI, is coupled in feedback between the first (for example, inverting) output and first input of the differential amplifier circuit 16a. A second integration capacitor 16d of the loop filter, having a capacitance value of CINTI, is coupled in feedback between the second (for example, non-inverting) output and second input of the differential amplifier circuit 16a.

The differential outputs of the differential amplifier circuit 16a are coupled, for example through one or more additional filter stages, to corresponding differential inputs of the quantizer 16e for the ΣΔ-ADC circuit 16, with the n-bit digital output of the quantizer applied to the input of the C-DAC 16b. As noted, the differential signal output of the C-DAC 16b is applied in negative feedback to the differential first and second inputs of the amplifier 16a for the loop filter.

Those skilled in the art will understand that the circuit illustration is somewhat simplified. To be clear, one or more other integrators can be present between the output of the first integrator 16a and the input of the quantizer 16e. Such further included integrators would, for example, effectuate a change in the order of the ΣΔ-ADC circuit 16 and are likely to be included for improved circuit performance. One skilled in the art is well capable of designing a loop filter circuit of desired order for implementation in the ΣΔ-ADC circuit 16.

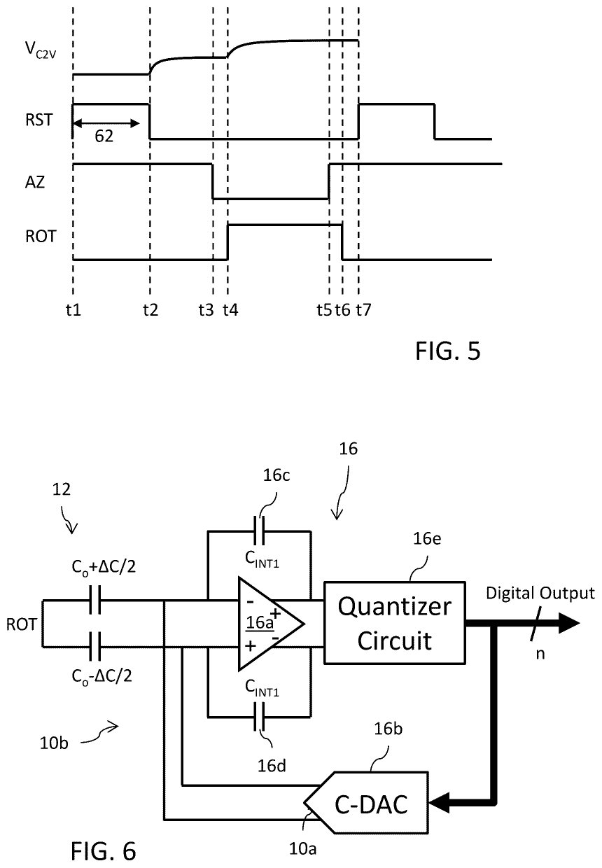

FIG. 5 shows a timing diagram for operation of a circuit which would include the circuit 10a shown in FIG. 4. The operation of the circuit is clocked through the phases of the signals RST, AZ (AZb) and ROT.

In a first phase from time t1 to time t2, the reset signal RST is logic 1, the auto-zero control signal is logic 1 and the MEMS clock ROT is at 0 volts. The charge amplifier 14 is in the reset condition with the virtual grounds of the differential amplifier 14a shorted to the common mode (reference) voltage V_{CM} and differential outputs shorted together. The capacitors 20a and 20c of the auto-zero circuit 20 are disconnected by switches 20b, 20d from the differential inputs of the amplifier 16a of the ΣΔ-ADC circuit 16. The second terminals of the capacitors 20a and 20c of the auto-zero circuit 20 are instead connected by switches 20b, 20d to the common mode voltage V_{CM}. A differential offset voltage of the charge amplifier 14 (referred to as V_{OPS}) in this case has no effect.

In a second phase from time t2 to time 3, the reset signal RST is logic 0, the auto-zero control signal is logic 1 and the MEMS clock ROT remains at 0 volts. The reset condition of the charge amplifier 14 is released. The differential offset voltage V_{OFS}, together with the kT/C noise generated on the capacitors of the MEMS sensor, are transferred to the output (voltage V_{C2V}) of the charge amplifier 14. These two undesired signals are stored on the capacitors 20a and 20c of the auto-zero circuit, where those capacitors 20c and 20d remain disconnected from the differential inputs of the amplifier 16a of the ΣΔ-ADC circuit 16 and connected to the common mode voltage V_{CM}. No signal is transferred at this point in time to the input of the ΣΔ-ADC circuit 16.

In a third phase from time t3 to time t7, the reset signal RST is logic 0, the auto-zero control signal AZ is logic 0 and the MEMS clock ROT transitions to the voltage V_{ROT}. The transition of the MEMS clock ROT from 0 to V_{ROT} volts generates a differential signal at the output of the charge amplifier 14 having an amplitude of V_{C2V}=V_{ROT}·ΔC/C_{C2V}. This signal is transferred to the differential inputs of the amplifier 16a of the ΣΔ-ADC circuit 16 since the capacitors 20a and 20c in this phase are connected through switches 20b and 20d to the ADC input. In this phase, neither the offset V_{OFS} nor the kT/C noise is transferred.

Within this third phase, there is a short delay from time t3 to time t4 before the transition of the MEMS clock ROT from 0 to V_{ROT} volts. The duration of the clock pulse for the MEMS clock ROT at the V_{ROT} voltage level lasts from time t4 to time t6. At time t5, between times t4 and t6, the auto-zero control signal AZ transitions to logic 1. At time t7, the timing process repeats for a next sampling of the MEMS sensor.

The main limitations of this architecture are related to the performance of the charge amplifier 14:
settling and accuracy of the charge amplifier 14 determine the quality of the signal, and so typically 9τ settling with 60 dB gain are required for the differential amplifier 14a, for example implemented as an operational transconductance amplifier (OTA), to preserve the stability of the performance over process, voltage, temperature (PVT) corners;
the maximum gain of the charge amplifier 14 is limited by its output voltage swing. Usually a two-stage amplifier must be used, which is intrinsically less efficient than other amplifier structures (such as, for example, an amplifier of telescopic-cascode type). The V_{C2V} voltage output swing must be kept as high as possible to minimize the ADC noise contributor;
in a typical situation, even with high V_{C2V} voltage swing, the ADC noise is not completely negligible, and the capacitors 20a and 20c must have a high enough capacitance CAZ to reduce their own kT/C noise. Values from 5 pF to 10 pF may be used; and
all these considerations (9τ settling/2-stage OTA/5 pF to 10 pF capacitances) lead to a power-hungry design.

An alternative solution for the circuit 10b is shown in FIG. 6, where the charge amplifier 14 is eliminated and the differential output of the MEMS sensor 12 is directly connected to the differential input of the ΣΔ-ADC circuit 16 at the loop filter. The circuit of FIG. 6 shows a first-order implementation of the ΣΔ-ADC circuit where the loop filter comprises a switched capacitor integrator. It will be understood that this illustration is by (simplified) example only and that higher order loop filter circuits are compatible with, and likely to be used by, the modulator circuit. In such a case, as previously noted, one or more additional integrators can be included in the modulator circuit to increase the order of the ADC circuit.

Notwithstanding the advantage of saving the charge amplifier 14 current and relaxing the whole system design, this architecture for circuit 10b has a drawback in that no solution is provided for performing the auto-zeroing operation which would cancel from the system the kT/C noise introduced by the reset operation performed on the capacitances of the MEMS sensor 12. As a result, this architecture is not suited for consumer applications or, in general, for low-noise applications.

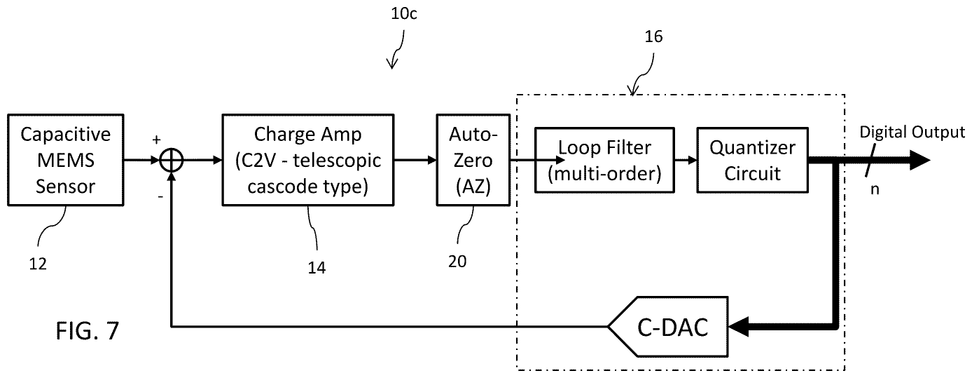

Reference is now made to FIG. 7 which shows a block diagram of an improved SC sensing chain 10c. The circuit shown in FIG. 7 differs from the circuit shown in FIG. 3 primarily with respect to the location for loop closure with the negative feedback signal output from the C-DAC of the ΣΔ-ADC circuit 16. The circuit implementation of FIG. 3, as shown by FIGS. 2 and 4, has the feedback signal output from the C-DAC of the ΣΔ-ADC circuit 16 applied to the signal chain between the output of the offset and low-frequency noise cancelation (auto-zeroing) circuit 20 and the input to the loop filter of the A-ADC circuit 16. In the circuit implementation of FIG. 6, however, the feedback signal output from the C-DAC of the ΣΔ-ADC circuit 16 is applied to the signal chain between the output of the MEMS sensor 12 and the input of the charge amplifier 14. In this context, the signal input to the charge amplifier 14 is a difference between the signal generated by the MEMS sensor and the feedback signal generated by the C-DAC, this difference being generated by the summation circuit.

The circuit solution of FIG. 7 presents a number of advantages:
the signal is removed from the output of the charge amplifier 14 that must accommodate just the quantization noise of the sigma-delta modulation. As a result, a telescopic cascode amplifier (have a design well-known to those skilled in the art) can be used for its implementation, simplifying the architecture and saving current (i.e., there is no need for using a two-stage OTA);
since the signal is no longer present at the output of the charge amplifier 14, the amplifier gain can be increased regardless of the signal that is generated from the capacitive MEMS sensor 12. This means that the noise of the ΣΔ-ADC circuit 16 is strongly relaxed, and the capacitance CAZ for the auto-zero capacitors 20a and 20c can be reduced (for example, to a value lower than 1 pF in practical cases). There is also an associated further current saving with this configuration presenting a structure simplification for the circuit;
since the charge amplifier 14 non-idealities (settling and accuracy) afflict both the signal that comes from the MEMS sensor and the signal that comes from the feedback C-DAC, their impact on the accuracy of the system is no longer critical. The performance of the analog-to-digital conversion operation over PVT corners with a 31/30 dB C2V OTA design are the same as is reached with a 9τ/60 dB design;
since the C-DAC feedback signal loop closure has been moved to the input of the charge amplifier 14, in the same position as the output from the MEMS sensor, the kT/C noise of the C-DAC is canceled from the systems thanks to the operation of the auto-zeroing circuit 20; and
considering the current saved in the charge amplifier 14 (for example, with use of telescopic-cascode amplifier with smaller capacitive load instead of two-stage amplifier) and the lower weight of the noise of the ΣΔ-ADC circuit 16 (that is strongly relaxed), the result is a low-noise, low-area, low-current consumption architecture.

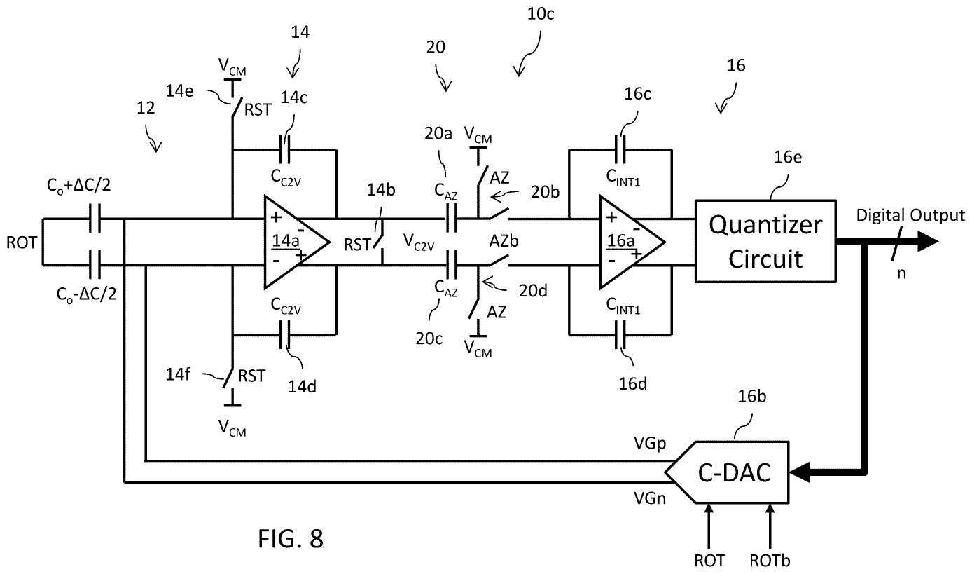

To clarify the concept, reference is made to FIG. 8 where the block scheme of the circuit 10c shown in FIG. 7 has been partially translated into a circuit schematic. The circuit of FIG. 8 shows a first-order implementation of the ΣΔ-ADC circuit where the loop filter comprises a switched capacitor integrator. It will be understood that this illustration is by (simplified) example only and that higher order loop filter circuits are compatible with, and likely to be used by, the modulator circuit. The MEMS sensor 12 generates a differential capacitance variation ΔC (which is the signal to be read) in response to variation of some external physical quantity (such as acceleration, angular rate, pressure, etc.) which is coupled, along with the differential negative feedback signal output from the first and second differential outputs of the C-DAC 16b, to the virtual ground of the charge amplifier 14.

The switched capacitor charge amplifier 14 includes a differential amplifier circuit 14a including a first (for example, non-inverting) input coupled to receive the differential signal component which is based on the capacitance

$${C}_{o} + \frac{Δ C}{2}$$

of the MEMS sensor 12 and the feedback output of the C-DAC 16b, and a second (for example, inverting) input coupled to receive the differential signal component which is based on the capacitance

$${C}_{o} - \frac{Δ C}{2}$$

of the MEMS sensor 12 and the feedback output of the C-DAC 16b. A square wave MEMS clock signal ROT is applied to a common connection node between the MEMS capacitors. A reset switch 14b is coupled between the first (for example, inverting) output and second (for example, non-inverting) output of the differential amplifier circuit 14a and actuated (i.e., closed) in response to assertion of a reset signal RST. A first capacitor 14c, having a capacitance value of C_{C2V}, is coupled in feedback between the first output and first input of the differential amplifier circuit 14a. A second capacitor 14d, having a capacitance value of C_{C2V}, is coupled in feedback between the second output and second input of the differential amplifier circuit 14a. A first common mode switch 14e is coupled between the first input of the differential amplifier circuit 14a and a common mode voltage V_{CM}. A second common mode switch 14f is coupled between the second input of the differential amplifier circuit 14a and the common mode voltage V_{CM}. The switches 14e and 14f are actuated in response to assertion of the reset signal RST.

The differential output voltage V_{C2V} of the differential amplifier circuit 14a is coupled to the input of the auto-zeroing circuit 20. The auto-zeroing circuit 20 includes a first auto-zero capacitor 20a, having a capacitance CAZ, with a first terminal coupled to the first output of the differential amplifier circuit 14a and a second terminal coupled to a first auto-zero switch 20b. A second auto-zero capacitor 20c, having a capacitance CAZ, has a first terminal coupled to the second output of the differential amplifier circuit 14a and a second terminal coupled to a second auto-zero switch 20d. The switching operation of the first and second auto-zero switches 20b and 20d is controlled by logically inverted auto-zero control signals AZ, AZb. When the auto-zero control signal AZ is asserted (and thus the auto-zero control signal AZb is deasserted), the first and second auto-zero switches 20b and 20d couple the second terminals of the capacitors 20a, 20c to the common mode voltage V_{CM}. Conversely, when the auto-zero control signal AZb is asserted (and thus the auto-zero control signal AZ is deasserted), the first and second auto-zero switches 20b and 20d couple the second terminals of the capacitors 20a, 20c to the differential inputs, respectively, of the ΣΔ-ADC circuit 16.

The loop filter of the ΣΔ-ADC circuit 16 includes a differential amplifier circuit 16a having a first (for example, non-inverting) input coupled to the first auto-zero switch 20b and a second (for example, inverting) input coupled to the second auto-zero switch 20d. A first integration capacitor 16c, having a capacitance value of CINTI, is coupled in feedback between the first (for example, inverting) output and first input of the differential amplifier circuit 16a. A second integration capacitor 16d, having a capacitance value of CINTI, is coupled in feedback between the second (for example, non-inverting) output and second input of the differential amplifier circuit 16a.

The differential outputs of the differential amplifier circuit 16a are coupled, for example through one or more additional filter stages, to corresponding differential inputs of the quantizer 16e, with the n-bit digital output of the quantizer applied to the input of the C-DAC 16b. The first and second differential outputs of the C-DAC 16b generate the feedback signal which is differentially applied at the first and second differential inputs, respectively of the amplifier 14a of the charge amplifier 14 (at the output of the MEMS sensor 12).

Those skilled in the art will understand that the circuit illustration is somewhat simplified. To be clear, one or more other integrators can be present between the output of the first integrator 16a and the input of the quantizer 16e. Such further included integrators would, for example, effectuate a change in the order of the ΣΔ-ADC circuit 16 and are likely to be included for improved circuit performance. One skilled in the art is well capable of designing a loop filter circuit of desired order for implementation in the ΣΔ-ADC circuit 16.

The timing diagram for the operation of a circuit which includes the circuit 10c, clocked through the phases of the signals RST, AZ (AZb) and ROT, is shown in FIG. 5.

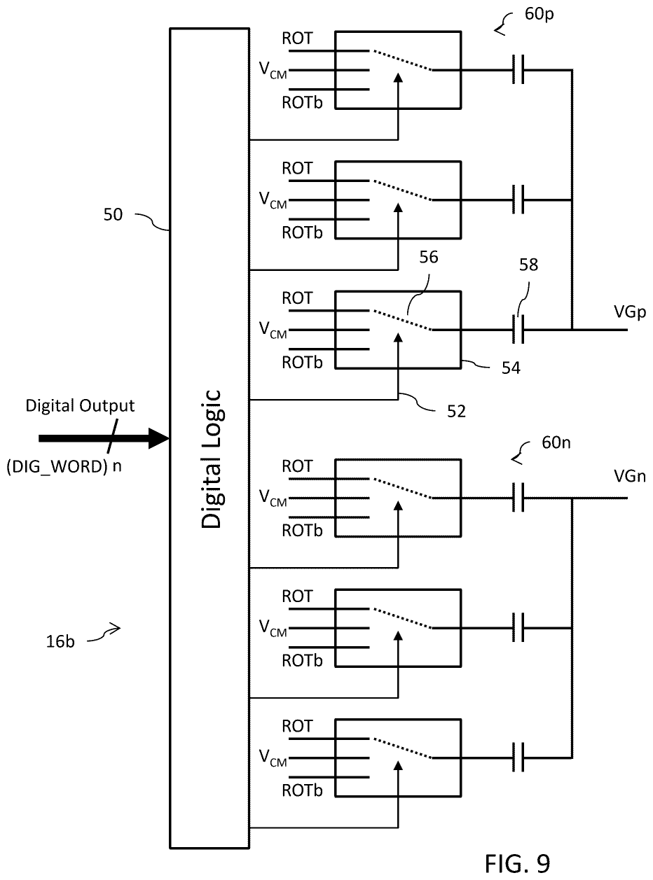

Reference is now made to FIG. 9 which shows an example implementation of a multi-level capacitive digital-to-analog converter (C-DAC) circuit 16b used in the circuit of FIG. 7. The illustrated of FIG. 9 shows, by example only, a seven-level circuit implementation. The C-DAC circuit 16b receives as inputs: an n-bit digital word (DIG_WORD) generated as the digital output from the quantizer; the MEMS sensor clock signal ROT, which is a voltage square wave between 0 and V_{ROT} volts, that is used also to drive the capacitive MEMS sensor 12; and the signal ROTb, which is a voltage square wave between V_{ROT} and 0 volts, with a same timing as the signal ROT but with opposite logic level (i.e., 180° out of phase).

The C-DAC circuit 16b injects an electrical charge, using the output differential signals VGp and VGn, in the virtual grounds of the operational amplifier 14a of the charge amplifier 14. The C-DAC circuit 16b used the voltages of the signals ROT and ROTb and the common mode voltage V_{CM} in order to compensate the charge that comes from the MEMS sensor. FIG. 8 illustrates a circuit for a seven-level DAC circuit, but those skilled in the art will understand that this is by example only and the C-DAC may be implemented with N-levels.

The received n-bit digital word DIG_WORD is input to a digital logic circuit 50 and decoded to selectively drive through control signals 52 the switching operation of a plurality of tri-level switches 54. In the illustrated example, three tri-level switches 54 are provided in a positive differential circuit portion 60p for generating the signal VGp and three tri-level switches 54 are provided in a negative differential circuit portion 60n for generating the signal VGn, where the signals VGp, VGn provide the differential feedback signal applied the virtual grounds of the operational amplifier 14a of the charge amplifier 14. The switching circuit 56 within each tri-level switch 54 selectively connects, to the first terminal of an associated capacitor 58, a selected one of: a) the common-mode reference voltage V_{CM}; b) the voltage of the MEMS sensor clock signal ROT; or c) the voltage of the logically inverted MEMS sensor clock signal ROTb. The second terminals of the capacitors 58 for each of the positive differential circuit portion 60p and negative differential circuit portion 60n are connected, respectively, to the common nodes where the signals VGp and VGn are output. It is important to note here that the signals ROT and ROTb are not fixed voltages, but rather are square wave signals alternating between 0 volts and V_{ROT} volts, and that transitions (leading or trailing edges) of the square wave occur only when the reset signal RESET is not asserted (see, FIG. 5). The common-mode reference voltage V_{CM} is selected by the switching circuit 56 within each tri-level switch 54 for contribution by capacitive coupling to the signals VGp, VGn when the decoded control signal 52, generated by the digital logic circuit 50 in response to the digital word DIG_WORD, indicates that no charge is to be injected through the feedback. One of the signal ROT or signal ROTb voltages is selected by the switching circuit 56 for contribution by capacitive coupling to the signals VGp, VGn when the decoded control signal 52, generated in response to the digital word DIG_WORD, indicates that charge is to be injected through the feedback. In this case, when the signal ROT voltage is selected by the switching circuit 56 of a given tri-level switch 54 in the circuit 60p for contribution by capacitive coupling to the generation of the signal VGp, the switching circuit 56 of the corresponding tri-level switch 54 in the circuit 60n for contribution to the generation of the signal VGn selects the signal ROTb voltage. Conversely, when the signal ROTb voltage is selected by the switching circuit 56 of a given tri-level switch 54 in the circuit 60p for contribution by capacitive coupling in generating the signal VGp, the switching circuit 56 of the corresponding tri-level switch 54 in the circuit 60n for contribution in generating the signal VGn selects the signal ROT voltage. Thus, it will be understood that the capacitors 58 used for generating the VGn signal are driven with the opposite signal ROT or ROTb which drives the capacitors 58 used for generating the VGp signal by capacitive coupling. Where the common-mode reference voltage V_{CM} is selected, it is applied by corresponding tri-level switches 54 in both circuits 60p and 60n for contribution by capacitive coupling in the generation of the signals VGp and VGn.

The digital word DIG_WORD of the digital signal that drives the C-DAC 16b is changed only within a safe timeframe where its variation has no impact on operation of the circuit. For example, this change can be made while in the reset phase (i.e., when the reset signal RST is asserted as indicated by the timeframe 62 in FIG. 5). This useful safe timeframe ends some time before the end of the reset phase in order to ensure that the C-DAC switches 56 are configured before the RESET release. In this way, the kT/C noise generated by the commutation of the DAC switches has no effect on the circuit since it is completely nulled by the connection of the Virtual Grounds of the amplifier (receiving differential feedback signals VGp and VGp) to the common mode voltage V_{CM}.

Reference is made, by example only, to the following showing configurations for telescopic-cascode amplifier design (all incorporated herein by reference): a) da Silva, at al., “Design of a telescopic operational amplifier using a semi-automatic synthesis,” Semantic Scholar, Corpus ID: 220657399, 2014; b) Jin, et al., “Analysis and design of fully differential gain-boosted telescopic cascode opamp,” 7th International Conference on Solid-State and Integrated Circuits Technology, 2004; c) Kouhalvandi, et al., “Design of a high gain telescopic-cascode operational amplifier based on the ZTC operation condition,” IEEE International Conference on Electronics, Circuits and Systems, 2017.

While the invention has been illustrated and described in detail in the drawings and foregoing description, such illustration and description are considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims.

What is claimed is:

1. A capacitive sensing circuit, comprising:
a switched capacitor charge to voltage (C2V) converter circuit having an input coupled to a capacitive sensor and configured to receive a negative feedback signal;
an offset and low-frequency noise cancelation circuit having an input coupled to an output of the switched capacitor C2V converter circuit; and
a sigma-delta analog-to-digital converter (ΣΔ-ADC) circuit including a loop filter coupled to an output of the offset and low-frequency noise cancelation circuit, a quantizer coupled to an output of the loop filter and configured to generate a digital signal, and a digital-to-analog converter circuit configured to generate the negative feedback signal from the digital signal.

2. The circuit of claim 1, wherein the digital signal is indicative of a sensed capacitive variation of the capacitive sensor.

3. The circuit of claim 2, wherein a square wave clock signal is applied to the capacitive sensor, and wherein the digital-to-analog converter circuit includes a tri-level switch circuit that generates the negative feedback signal by capacitively coupling, in response to the digital signal, a selected one of the square wave clock signal, an inversion of the square wave clock signal, and a common mode voltage to an output node where the negative feedback signal is generated.

4. The circuit of claim 3, wherein the switched capacitor C2V converter circuit responds to assertion of a reset signal to periodically reset a voltage of the switched capacitor C2V converter circuit to the common mode voltage, wherein an output of the switched capacitor C2V converter circuit is reset in response to assertion of the reset signal, and wherein changes in the digital signal occur only when the reset signal is asserted.

5. The circuit of claim 3, wherein the digital-to-analog converter circuit further includes a logic circuit configured to decode a digital word of the digital signal and generate a switch control signal for controlling selection by the tri-level switch circuit.

6. The circuit of claim 3, wherein edge transition of the square wave clock signal occurs only when the reset signal is not asserted.

7. The circuit of claim 6, wherein the offset and low-frequency noise cancelation circuit responds to assertion of a control signal to connect to the common mode voltage, and wherein the control signal is asserted at least when the reset signal is asserted.

8. The circuit of claim 1, wherein the switched capacitor C2V converter circuit comprises a telescopic cascode amplifier.

9. The circuit of claim 1, wherein the switched capacitor C2V converter circuit comprises: an amplifier having an input and an output; a capacitor coupled between the input and output of the amplifier; and a switch, controlled by a reset signal, to selectively connect the input of the amplifier to a reset voltage.

10. The circuit of claim 9, wherein the amplifier is a differential amplifier and the reset voltage is a common mode voltage.

11. The circuit of claim 1, wherein the offset and low-frequency noise cancelation circuit comprises a capacitor having a first terminal coupled to the output of the switched capacitor C2V converter circuit and a switching circuit configured to connect a second terminal of the capacitor to a reset voltage in response to assertion of a control signal and connect the second terminal of the capacitor to an input of the ΣΔ-ADC circuit in response to deassertion of the control signal.

12. The circuit of claim 11, wherein the offset and low-frequency noise cancelation circuit is differential and the reset voltage is a common mode voltage.

13. The circuit of claim 1, wherein the offset and low-frequency noise cancelation circuit is an auto-zeroing (AZ) circuit.

14. The circuit of claim 1, wherein the negative feedback signal output by the digital-to-analog converter circuit is directly connected to the input of the switched capacitor C2V converter circuit.

15. A method, comprising:
generating a difference signal between a capacitive sensor output signal and a feedback signal;
performing offset and low-frequency noise cancelation on the difference signal to generate a first signal;
filtering the first signal to generate a second signal;
quantizing the second signal to generate a digital signal; and
performing a digital to analog signal conversion to convert the digital signal to generate the feedback signal.

16. The method of claim 15, wherein generating the difference signal comprises performing a charge to voltage conversion operation which converts a charge of the difference signal to a voltage signal, and wherein performing offset and low-frequency noise cancelation is performed on the voltage signal.

17. The method of claim 16, further comprising directly applying the feedback signal to an input of the charge to voltage conversion operation.

18. The method of claim 16, wherein the capacitive sensor output signal is generated by a capacitive sensor, further comprising:
applying a square wave clock signal is applied to the capacitive sensor; and
wherein performing the digital to analog signal conversion comprises generating the feedback signal by capacitively coupling, in response to the digital signal, a selected one of the square wave clock signal, an inversion of the square wave clock signal, and a common mode voltage.

19. The method of claim 18, further comprising:
resetting the charge to voltage conversion operation to the common mode voltage in response to a reset signal; and
wherein change of the digital signal occurs only when the reset signal is asserted.

20. The method of claim 19, wherein edge transition of the square wave clock signal occurs only when the reset signal is not asserted.
